(19) United States
(12) Patent Application Publication
(10) Pub. No.: US 2025/0180669 A1
(43) Pub. Date: Jun. 5, 2025

(54) TESTING CIRCUIT

(71) Applicant: TEXAS INSTRUMENTS INCORPORATED, DALLAS, TX (US)

(72) Inventors: SWARNA SAGAR, BENGALURU (IN); GEORGE THOTTAN, BANGALORE (IN); ABHINAY PATIL, Bangalore (IN)

(21) Appl. No.: 18/621,603

(22) Filed: Mar. 29, 2024

(30) Foreign Application Priority Data
Dec. 5, 2023 (IN) 202341082671

(51) Int. Cl. G01R 31/74

(52) U.S. Cl. CPC G01R 31/74

(57) ABSTRACT

A circuit for testing a DUT (device under test) includes an inductor coupled to a first switch, and the first switch is coupled to a second switch. The circuit includes a test module coupled to the first switch and the second switch. The test module includes a DUT. The circuit also includes a TVS (transient voltage suppressor) coupled to the second switch.

### CROSS-REFERENCE TO RELATED APPLICATION

This application claims the benefit of priority to Indian Provisional Application No. 202341082671, filed in the Indian Patent Office on 5 Dec. 2023 the entirety of which is herein incorporated by reference.

### TECHNICAL FIELD

This description relates to a circuit for determining characteristics of a DUT (device under test).

### BACKGROUND

An electronic fuse, commonly referred to as an eFuse, serves as a resettable overcurrent protection device within electronic circuits, utilizing semiconductor technology to enhance control and ensure safety. Conventional fuses, which permanently disconnect the circuit by melting under excessive current, differ from eFuses in that eFuses are designed for non-destructive interruption and resettable for multiple uses. The operation of an eFuse relies on components such as FETs (field effect transistors) to monitor the flow of current. When current levels exceed predefined limits, the eFuse acts quickly to break the circuit, thereby preventing damage to electronic components, overheating or potential fire hazards.

Features of eFuses include resettable functionality, allowing reactivation post-tripping, either automatically or manually. Accordingly, eFuses provide accurate current sensing for rapid response to overcurrent conditions. Additional protective functions may be integrated into eFuses, such as overvoltage protection, under-voltage lockout, thermal shutdown and fault indication outputs. The compact design of eFuses enables a small footprint on printed circuit boards, facilitating integration into IC (integrated circuit) packages.

### SUMMARY

A first example relates to a circuit for determining characteristics of a DUT (device under test), the circuit includes an inductor coupled to a first switch. The first switch is coupled to a second switch. The circuit includes a test module coupled to the first switch and the second switch. The test module includes a DUT. The circuit also includes a TVS (transient voltage suppressor) coupled to the second switch.

A second example relates to a circuit for determining characteristics of a DUT. The circuit includes an inductor configured to store energy and a first switch coupled to the inductor and operable to provide a charging path for the inductor. The circuit includes a second switch coupled to the first switch. The first switch and the second switch operate in concert to control a discharge of the inductor through a first discharge path, and the second switch is operable to provide a second discharge path for the inductor responsive to tolling a DUT avalanche interval. The circuit includes a TVS (transient voltage suppressor) on the second discharge path. The TVS being coupled to the second switch, wherein the energy from the inductor is diverted to the TVS responsive to the tolling of the DUT avalanche interval. The circuit includes a test module on the first discharge path that is coupled to the first switch and the second switch. The test module connects the DUT to a current output by the inductor during the DUT avalanche interval for testing current ratings of the DUT.

A third example relates to a method for determining characteristics of a DUT closing a first switch of a circuit to pre-charge an inductor of the circuit. The method includes opening the first switch to discharge the inductor through the DUT to apply a transient fault condition for a DUT avalanche interval. The method also includes measuring a response of the DUT to the transient fault condition and closing a second switch responsive to tolling the DUT avalanche interval to divert current from the inductor to a TVS.

### BRIEF DESCRIPTION OF THE DRAWINGS

FIG. 1 illustrates an example of a test circuit for measuring a response to transient fault conditions provided to a DUT (device under test).

FIG. 2 illustrates an example of another example test circuit for measuring a response to transient fault conditions provided to a DUT.

FIG. 3 illustrates graphs for responses of components of the test circuit of FIG. 2 plotted as a function of time.

FIG. 4 illustrates an example of an NFET (n-channel field effect transistor) that is employable to implement the DUT of FIG. 2 and an equivalent large signal model for the NFET.

FIGS. 5A and 5B illustrate graphs that plot a drain current, ID of the NFET of FIG. 4 as a function of a drain-to-source voltage.

FIG. 6A illustrates a chart of a sample of measured response characteristics of the NFET 400 during a DUT avalanche interval.

FIG. 6B illustrates a graph that plots the voltage of the NFET of FIG. 4 as a function of the current.

FIGS. 7A, 7B and 7C illustrate graphs that show measured results of a response of the DUT of FIG. 2 to a first example of transient fault conditions during a DUT avalanche interval.

FIGS. 8A, 8B and 8C illustrate graphs that show measured results of a response of the DUT of FIG. 2 to a second example of transient fault conditions during a DUT avalanche interval.

FIGS. 9A, 9B and 9C illustrate graphs that show measured results of a response of the DUT of FIG. 2 to a third example of transient fault conditions during a DUT avalanche interval.

FIGS. 10A and 10B illustrate graphs that show measured results of a response of the DUT of FIG. 2 to a fourth example of transient fault conditions during a DUT avalanche interval.

FIGS. 11A, 11B and 11C illustrate graphs that show measured results of a response of the DUT of FIG. 2 to a first example of repetitive transient fault conditions during a DUT avalanche interval.

FIGS. 12A, 12B and 12C illustrate graphs that show measured results of a response of the DUT of FIG. 2 to a second example of repetitive transient fault conditions during a DUT avalanche interval.

FIGS. 13A, 13B and 13C illustrate graphs that show measured results of a response of the DUT of FIG. 2 to a third example of repetitive transient fault conditions during a DUT avalanche interval.

FIG. 14 illustrates a block diagram of a circuit that illustrates an eFuse coupled between a power supply and a load.

FIG. 15 illustrates an example of a method for determining characteristics a DUT.

### DETAILED DESCRIPTION

This description relates to a test circuit for determining characteristics (e.g., operating characteristics) of a DUT (device under test), such as an eFuse (alternatively referred to as an electronic fuse). More specifically, in some examples, the test circuit measures a response to transient fault conditions applied to the DUT. The test circuit is employed to determine a transient voltage rating and/or a current rating of the DUT, which enables users of the DUT to ensure that the DUT can handle voltage/current spikes during fault conditions without sustaining damage.

The rating process begins with the pre-charging of an inductor within the test circuit. This inductor is then discharged through the DUT to simulate a transient fault condition, such as a short circuit or overload, that the DUT might encounter during normal operation. The response of the DUT to this simulated transient fault condition is measured to assess performance and reliability.

To achieve precise control over the testing process, the circuit includes a first switch and a second switch that are controllable to initiate the pre-charging of the inductor and to discharge the inductor for a precisely controlled interval of time, referred to as a DUT avalanche interval. The DUT avalanche interval is designed to expose the DUT to the discharged current of for a predetermined time duration, allowing for the monitoring of the voltage and current across the DUT during this DUT avalanche interval.

In response to tolling the DUT avalanche interval, the second switch closes to divert energy (current, more particularly) discharged from the inductor to a TVS (transient voltage suppressor). The TVS clamps the voltage across the DUT after the DUT avalanche interval. The response of the DUT to the transient fault conditions is measured and recorded for subsequent analysis to determine a transient voltage and current rating of the DUT, which characterizes an ability of the DUT (e.g., an eFuse) to withstand transient voltage spikes. Thus, in examples where the DUT is an eFuse, the transient voltage and current rating of the eFuse characterize an ability of the eFuse to protect a downstream load during an overload and/or a short circuit condition.

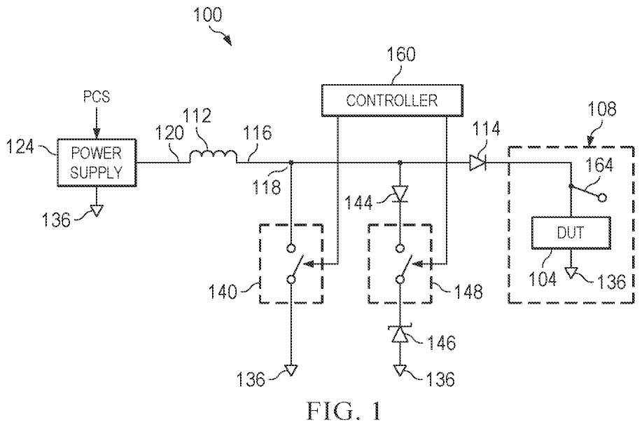

FIG. 1 illustrates an example of a test circuit 100 for measuring a response to transient fault conditions provided to a DUT 104, such as an eFuse (alternatively referred to as an electronic fuse). The transient fault conditions represent an overvoltage and/or an overcurrent condition provided to the DUT 104 for a controllable interval of time, which time interval is referred to as a DUT avalanche interval.

The test circuit 100 includes a test module 108 (alternatively referred to as an evaluation module) that includes the DUT 104. The test module 108 is coupled to an inductor 112. Additionally, a diode 114 is coupled between the inductor 112 and the test module 108. In addition to the DUT 104, in various examples, the test module 108 includes components that facilitate biasing, DUT connections, control pins, etc. More specifically, the inductor 112 has a first node 116 coupled to a switch node 118 of the test circuit 100 and a second node 120 coupled to a positive output terminal of a power supply 124, and the test module 108 is coupled to the switch node 118 through the diode 114.

A first switch 140 is also coupled to the switch node 118 and the ground node 136, such that the first switch 140 is coupled in parallel with the test module 108. An anode of a diode 144 is coupled to the switch node 118, and a cathode of the diode 144 is coupled to a second switch 148. The second switch 148 is coupled to a TVS 146, such as a unidirectional TVS. A cathode of the TVS 146 is coupled to the second switch 148 and an anode of the TVS 146 is coupled to the ground node 136.

The first switch 140 and the second switch 148 are implemented as normally open switches that are controlled by a controller 160. More particularly, the controller outputs signals, namely a first control signal to the first switch 140 and a second control signal to the second switch 148. In some examples, the second switch 148 are implemented with transistors, such as NFETs (N-channel field effect transistors). In such examples, assertion of the first control signal, causes the first switch 140 to close. Closing of the first switch 140 shorts the switch node 118 to the ground node 136. De-assertion of the first control signal causes the 140 to open, de-coupling the switch node 118 from the ground node 136. Additionally, assertion of the second control signal couples the cathode of the diode 144 to the cathode of the TVS 146. Conversely, de-assertion of the second control signal causes the second switch 148 to open. Opening of the second switch 148 decouples the diode 144 from the TVS 146.

The controller 160 is implemented with a microcontroller or other device that provides the control signals. In some examples, the controller 160 is a stand-alone device. In other examples, the controller 160 interfaces with an external system, such as a computer.

As used herein, assertion of a signal, such as assertion of the first control signal and the second control signal, refers to outputting a state of the signal that causes the receiving device to change from an off-state (e.g., a default state) to an on-state (e.g., an activated state). Thus, in examples where the first switch 140 and the second switch 148 are implemented with NFETs, assertion of the first control signal and/or the second control signal represents outputting a logic high (e.g., 5 V) signal to a gate of the first switch 140 and/or the second switch 148, and de-assertion of the first control signal and/or the second control signal represents outputting a logic low signal (e.g., 0 V) to the gate of the first switch 140 and/or the second switch 148.

The power supply 124 is a DC (direct current) power supply that outputs a voltage on the second node 120 of the inductor 112 responsive to a power control signal (labeled PCS in FIG. 1). In some examples, the power control signal is provided from an external system, such as a computer, such that the power supply 124 is controlled through software. In an alternative example, the power control signal is provided from the controller 160. In some examples, assertion of the power control signal causes the power supply 124 to output an output voltage to the second node 120 of the inductor 112. In some examples, the output voltage is about 5-20 V (e.g., 7 V). Conversely, de-assertion of the power control signal causes the power supply 124 to cease outputting of the output voltage.

The test circuit 100 includes a probe 164 that measures a voltage and/or a current across the DUT 104. In some examples, the output of the probe 164 is provided to a controller 160 or an ADC (analog-to-digital converter). In some examples, an output (e.g., a digital value) is provided to an external system, such as a computer for storage and analysis.

In operation, the test circuit 100 has four states: (i) an off state, (ii) an inductor charging state, (iii) a DUT avalanche state and (iv) a TVS clamp state. In the off state, the control signals output by the controller 160 are de-asserted, such that no current flows through the test circuit 100. In the inductor charging state, the first switch 140 is closed and the second switch 148 is opened, such that the inductor is coupled to a charging path that includes the first switch 140. Thus, to initiate the inductor charging state, the power control signal output to the power supply 124 and the first control signal output to the first switch 140 are asserted, and the second control signal output to the second switch 148 is de-asserted. Thus, in the charging state, the inductor 112 is charged to ramp up stored current.

Responsive to reaching a desired peaked level, the controller 160 de-asserts the first switch 140, causing the first switch 140 to open, and continues to de-assert the second control signal, keeping the second switch 148 open, thereby transitioning the test circuit 100 to the DUT avalanche state. In the DUT avalanche state, current stored in the inductor 112 is rapidly discharged through a first discharge path that includes the test module 108, and the DUT 104, more specifically for a controllable amount of time, which is referred to as the DUT avalanche interval. Stated differently, the inductor current is discharged through the DUT 104 during the DUT avalanche interval. Additionally, because both the first switch 140 and the second switch 148 are opened, this time interval is alternatively referred to as a deadtime interval between the first switch 140 and the second switch 148. In this manner, the first switch 140 and the second switch 148 operate in concert to control a discharge of the inductor through a first discharge path and through the DUT 104.

During the DUT avalanche interval, a voltage and/or a current across the DUT 104 is measured and recorded. In some examples, the voltage across the DUT 104 is about 12 V to about 100 V (e.g., about 23-27 V in some examples), and the current across the DUT 104 is in a range of about 50 amperes (A) to about 300 A. Moreover, the DUT avalanche interval is about 1 microsecond (μs) or less, such as a range of about 100 nanoseconds (ns) to about 1 μs. The duration of the DUT avalanche interval is adjustable based on the first timing control signal provided to the first switch 140 and the second timing control signal provided to the second switch 148. The response of the DUT 104 during the DUT avalanche interval is employable to determine reliability characteristics of the DUT 104. Accordingly, during the DUT avalanche interval, transient fault conditions (e.g., over voltage and/or over current) are applied to the DUT 104.

In response to tolling the DUT avalanche interval, the controller 160 asserts the second control signal, causing the second switch 148 to close, such that inductor current (energy, more generally) is diverted from the test module 108 and to a second discharge path that includes the diode 144 and the TVS 146, such that the second switch 148 is operable to provide the second discharge path for the inductor 112. Closing of the second switch 148 causes the test circuit 100 to transition to the TVS clamp state. In the TVS clamp state, the inductor current discharges across the diode 144 and the TVS 146, such that the TVS 146 clamps the voltage across the DUT 104 at a level defined by operational characteristics of the TVS 146. More particularly, in response to a voltage exceeding a forward voltage of the diode 144 and exceeding a breakdown voltage of the TVS 146, the TVS 146 conducts, thereby clamping the voltage. Accordingly, the breakdown voltage of the TVS 146 defines the clamping voltage of the TVS 146. During the TVS clamp state, the current stored in the inductor 112 is discharged to nearly 0 A.

In some situations, in response to tolling the TVS clamping state the test circuit 100 returns to the off-state. In other examples, multiple DUT avalanche intervals are applied on the DUT 104 to test reliability of the DUT 104. In such a situation, the controller 160 can reassert and de-assert the control signals to the power supply 124, the first switch 140 and the second switch 148 to transition the test circuit 100 to the inductor charging state, the DUT avalanche state and the TVS clamp state. Accordingly, the impact of multiple transient fault conditions (multiple instances of the DUT avalanche interval) can be measured and recorded. Moreover, the architecture of the test circuit 100, particularly the first switch 140 and the second switch 148 enables precise controlling of the amplitude of the fault conditions and the duration of the DUT avalanche interval to determine transient voltage and current ratings for the DUT 104. In this manner, the DUT 104 (e.g., an eFuse) can be confidently deployed in other circuits that rely on particular operational characteristics present in the fault conditions applied during the DUT avalanche interval. Thus, in examples where the DUT 104 is an eFuse, the transient voltage and current rating of the eFuse characterize an ability of the eFuse to protect a downstream load during an overload and/or a short circuit condition.

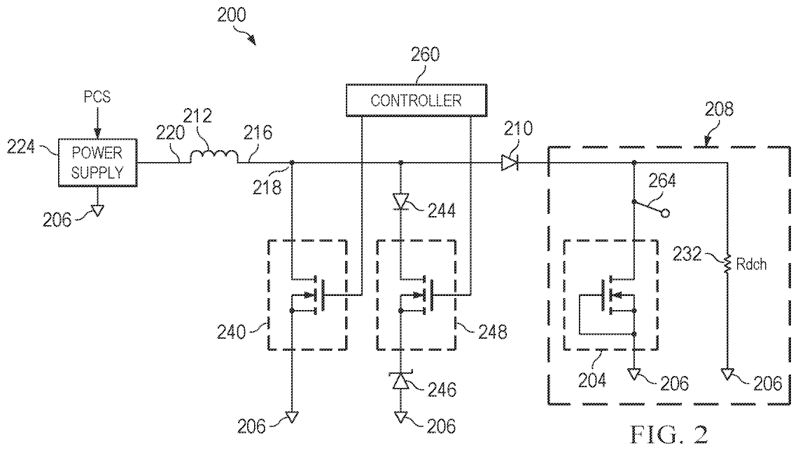

FIG. 2 illustrates an example of a test circuit 200 that is employable to implement the test circuit 100 of FIG. 1. The test circuit 200 is employable for measuring a response to transient fault conditions provided to a DUT 204, such as an eFuse. The transient fault conditions represent an overvoltage and/or an overcurrent condition provided to the DUT 204 for a controllable DUT avalanche interval (an interval of time).

The test circuit 200 includes a test module 208 that includes the DUT 204. The DUT 204 is represented as an NFET (e.g., a power NFET) that has a gate coupled to a source and a ground node 206. The test circuit 200 includes an inductor 212 coupled to the test module 208 through a diode 210. More specifically, the inductor 212 has a first node 216 coupled to a switch node 218 of the test circuit 200 and a second node 220 coupled to a positive output terminal of a power supply 224, and the test module 208 is coupled to the switch node 218 through the diode 210. The test circuit 200 includes a diode 210 coupled in series with the test module 208. More specifically, the diode 210 has an anode coupled to the switch node 218 and a cathode coupled to a drain of the DUT 204 and a discharge resistor 232, Rdch. The test module 208 also include other components needed for biasing, DUT connections, controller pins, etc. The discharge resistor 232 has a resistance of about 1 kilohm (kΩ) to about 10 megaohm (MΩ) is some examples. The discharge resistor 232 is coupled in parallel with the DUT 204, such that the discharge resistor 232 is also coupled to the ground node 206.

A drain of a first NFET 240 is also coupled to the switch node 218 and a source of the first NFET 240 is coupled to the ground node 206, such that the first NFET 240 is coupled in parallel with the test module 208. The first NFET 240 is employable to implement the first switch 140 of FIG. 1. An anode of a diode 244 is coupled to the switch node 218, and a cathode of the diode 244 is coupled to a drain of a second NFET 248. The second NFET 248 is employable to implement the second switch 148 of FIG. 1. The second NFET 248 is also coupled to a TVS 246. In the test circuit 200, the TVS 246 is unidirectional, and a cathode of the TVS 246 is coupled to a source of the second NFET 248 and an anode of the TVS 246 is coupled to the ground node 206.

The first NFET 240 and the second NFET 248 are implemented as enhancement mode NFETs that are turned off and operate in the cut-off region by default. However, in other examples, other types of transistors, including p-channel FETs are employable. A gate of the first NFET 240 and a gate of the second NFET 248 are coupled to outputs of a controller 260. More particularly, the controller 260 outputs signals, namely a first control signal the gate of the first NFET 240 and a second control signal to the gate of the second NFET 248. In such examples, assertion of the first control signal, such as a logic high (e.g., 5 V signal), causes the first NFET 240 to turn-on and transition to the ohmic region, which is equivalent to closing a switch. Turning-on the first NFET 240 shorts the switch node 218 to the ground node 206. De-assertion of the first control signal, such that a logic low (e.g., 0 V) signal is provided to the gate of the first NFET 240 causes the 240 to turn-off and transition to the cutoff region, de-coupling the switch node 218 from the ground node 206. Turning off the first NFET 240 is equivalent to opening the switch. Additionally, assertion of the second control signal, such that a logic high signal is applied to the gate of the second NFET (e.g., logic high) causes the second NFET 248 to turn-on, equivalent to closing a switch. Turning-on the second NFET couples the cathode of the diode 244 to the cathode of the TVS 246. Conversely, de-assertion of the second control signal, such that a logic low signal is provided to the gate of the second NFET 248, causes the second NFET 248 to turn off, causing the second NFET 248 to transition to the cutoff region, equivalent to opening the switch. Turning off the second NFET 248 decouples the diode 244 and the TVS 246.

The controller 260 is implemented with a microcontroller or other device that provides the control signals. In some examples, the controller 260 is a stand-alone device. In other examples, the controller 260 interfaces with an external system, such as a computer.

The power supply 224 is a DC (direct current) power supply that outputs a voltage on the second node 220 of the inductor 212 in response to a power control signal labeled PCS in FIG. 2. The power control signal is provided form an external system in some examples, such as an external computer, such that the power supply 224 is software controlled. In other examples, the power control signal is output from the controller 260. In some examples, assertion of the power control signal causes the power supply 224 to output an output voltage to the second node 220 of the inductor 212. In some examples, the output voltage is about 5-20 V (e.g., 7 V). Conversely, de-assertion of the power control signal causes the power supply 224 to cease application of the output voltage.

The test circuit 200 includes a probe 264 that measures a voltage and/or a current across the DUT 204. In some examples, the output of the probe 264 is provided to the controller 260 or an ADC (analog-to-digital converter) for recordation. In some examples, a digital value is provided to an external computer for the recordation and analysis.

In operation, the test circuit 200 has four states: (i) an off state, (ii) an inductor charging state, (iii) a DUT avalanche state and (iv) a TVS clamp state. In the off state, the control signals output by the controller 260 are de-asserted, such that no current flows through the test circuit 200. In the inductor charging state, the first NFET 240 is turned-on and the second NFET 248 is turned-off. Thus, to initiate the inductor charging state, the power control signal output to the power supply 224 and the first control signal output to the first NFET 240 are asserted turning-on the first NFET 240. Additionally, to initiate the inductor charging state, the second control signal output to the second NFET 248 is de-asserted, such that the second NFET 248 is turned-off. Thus, in the charging state, the inductor 212 coupled to a charging path that includes the first NFET 240, such that the inductor 212 is charged to ramp up stored current (or energy, more generally) to a peak level.

Responsive to reaching the peak level, the controller 260 de-asserts the first control signal provided to the first NFET 240, causing the first NFET 240 to turn-off, and continues to de-assert the second control signal, keeping the second NFET 248 turned-off, thereby transitioning the test circuit 200 to the DUT avalanche state. In the DUT avalanche state, current stored in the inductor 212 is rapidly discharged through a first discharge path, wherein the test module 208 is on the first discharge path, such that the inductor current is discharged through the DUT 204 for a controllable amount of time, which is referred to as the DUT avalanche interval. Stated differently, the first NFET 240 and the second NFET 248 operate in concert to control a discharge of the inductor through the first discharge path and to the DUT 204. Additionally, because both the first NFET 240 and the second NFET 248 are opened, this time interval is alternatively referred to as a deadtime interval between the first NFET 240 and the second NFET 248. Additionally, the duration of the DUT avalanche interval is controlled by a timing of the first control signal and the second control signal. More specifically, the controller adjusts the timing of the first control signal and/or the second control signal to vary the duration of the DUT avalanche interval.

In response to tolling the DUT avalanche interval, the controller 260 asserts the second control signal, causing the second NFET 248 to turn-off, such that current (energy, more generally) is diverted from the first discharge path to a second discharge path that includes the diode 244 and the TVS 246, such that the second NFET 248 is operable to provide the second discharge path for the inductor 212. In this manner, the inductor current is diverted from the DUT 204 and to the TVS 246. More generally, turning on the second NFET 248 causes the test circuit 200 to transition to the TVS clamp state. In the TVS clamp state, the TVS 246 clamps the voltage across the DUT 204 at a level defined by operational characteristics of the TVS 246. More particularly, in response to a voltage exceeding a forward voltage of the diode 244 and exceeding a breakdown voltage of the TVS 246, the diode 244 and the TVS 246 conduct, thereby clamping the voltage. Accordingly, the breakdown voltage of the TVS 246 defines the clamping voltage of the TVS 246. The discharge resistor 232 controls modulation of a fall time of voltage across the DUT 204 in the TVS clamp state. During the TVS clamp state, the current stored in the inductor 212 is discharged to nearly 0 A.

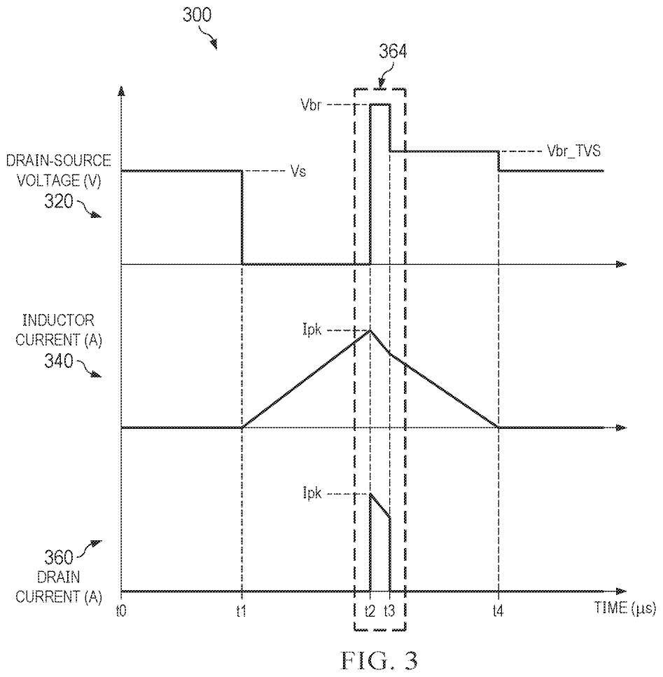

FIG. 3 illustrates charts 300 representing components of the test circuit 200 of FIG. 2 plotted as a function of time (e.g., in μs), and each chart is plotted over the same time interval. A first graph 320 plots a drain-source voltage of the DUT 204 of FIG. 2 as a function of time. A second graph 340 plots an inductor current of the inductor 212 of FIG. 2 as a function of time. A third graph 360 plots a drain current of the DUT 204 of FIG. 2.

In the charts 300, from time, t0 to time t1, the test circuit is turned off, such that there is about 0 inductor current (as illustrated by the second graph 340) and 0 drain current, as indicated by the third graph 360. Additionally, the drain-to-source voltage, VDS of the DUT 204 is equal to the source voltage, Vs. At time t1, the test circuit 200 transitions to the inductor charging state. The test circuit 200 operates in the inductor charging state from time t1 to time t2. In the inductor charging state, the DUT is short circuited by the first NFET 240 of FIG. 2, such that the drain current of the DUT 204 and the drain-source voltage of the DUT 204 are both about 0, as illustrated by the first graph 320 and the third graph 360. Additionally, as illustrated by the second graph 340, the inductor current of the inductor 212 ramps from 0 A to a peak current, Ipk. The amplitude of Ipk is controllable by a duration of the charging state (the interval of time between times t1 and t2). In various examples, the peak current, Ipk is in a range from about 50 A to about 300 A.

At time t2, the test circuit 200 transitions to the DUT avalanche state. The test circuit 200 operates in the DUT avalanche state from times t2 to t3, represented as a DUT avalanche interval 364. The DUT avalanche interval 364 is about 1 us or less (e.g., about 100 ns to about 1 μs in some examples). During the DUT avalanche interval 364, as illustrated by the first graph 320, the drain-to-source voltage reaches a breakdown voltage, Vbr.

As illustrated by the second graph 340 and the third graph 360, during the DUT avalanche interval 364, the current from the inductor 212 is rapidly discharged across the DUT 204. This rapid discharge applies transient fault conditions on the DUT 204. Thus, during the DUT avalanche interval 364, a voltage and/or a current across the DUT 204 is measured and recorded. In some examples, the voltage across the DUT 204 is about 22 V to about 100 V (e.g., about 23-27 V in some examples), and the current across the DUT 204 is in a range of about 50 amperes (A) to about 300 A. The response of the DUT 204 during the DUT avalanche interval is employable to determine reliability characteristics of the DUT 204. Accordingly, during the DUT avalanche interval, transient fault conditions (e.g., over voltage and/or over current) are applied to the DUT 204.

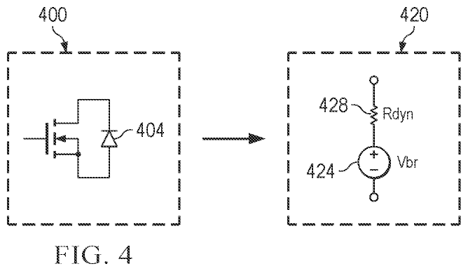

FIG. 4 illustrates an example of an NFET 400 that is employable to implement the DUT 204 of FIG. 2 and an equivalent large signal model 420 for the NFET 400. As illustrated, the NFET 400 has a body diode 404 with an anode of the body diode 404 connected to the source of the NFET 400 and a cathode connected to the drain of the NFET 400. As illustrated by the equivalent large signal model 420, the body diode 404 is represented with a DC voltage source 424 that has a voltage of Vbr, the breakdown voltage, and a dynamic resistance 428, Rdyn. The dynamic resistance 428 represents the resistance that characterizes a behavior of the body diode 404 in a reverse conduction region of the body diode 404.

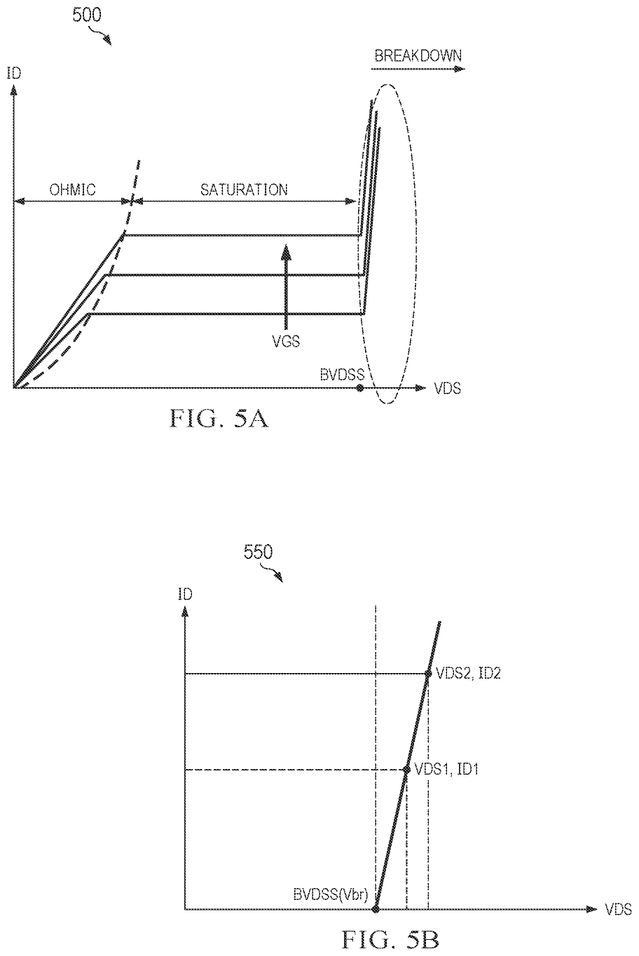

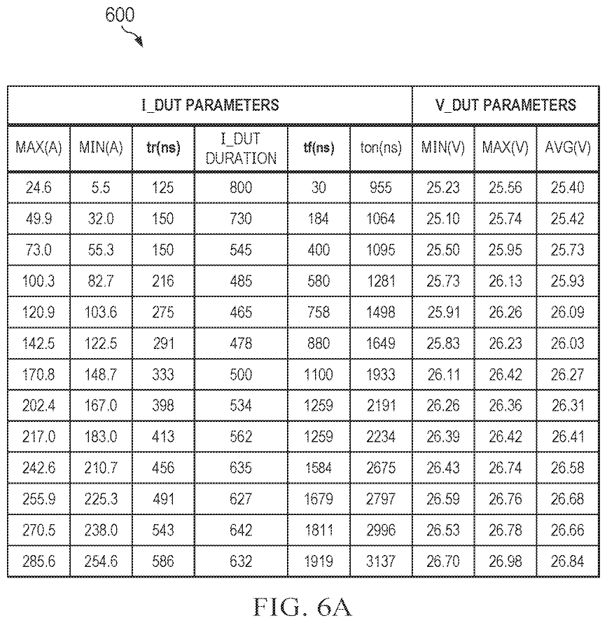

FIGS. 5A and 5B plot a drain current, ID of the NFET 400 as a function of a drain-to-source voltage, VDS of the NFET 400 of FIG. 4. More particularly, FIG. 5A is a first chart 500 that plots the drain current, ID as a function of the drain-to-source voltage, VDS for different gate-to-source voltages, VGS of the NFET 400. As illustrated, as the drain-to-source voltage, VDS increases, the NFET 400 transitions from the Ohmic (linear) region, to the saturation region and to the breakdown region. More particularly, the NFET 400 transitions to the breakdown region in response to the drain-to-source voltage, VDS reaching a drain-source breakdown voltage, BVDSS. The drain-source breakdown voltage, BVDSS is a parameter that specifies the maximum drain-to-source voltage that the NFET 400 can withstand without entering avalanche breakdown. In other words, drain-source breakdown voltage, BVDSS is the voltage at which the drain-to-source junction begins to conduct in reverse due to the avalanche effect, which leads to an uncontrolled increase in current.

FIG. 5B illustrates a second chart 550 that plots drain current, ID as a function of the drain-to-source voltage of the NFET 400 for a single gate-to-source voltage VGS. Additionally, the second chart 550 is scaled for clarity to expand a visual representation of the breakdown region of the NFET 400. Moreover, a value for the dynamic resistance 428, Rdyn can be calculated by measuring (or simulating) the drain current, ID for different drain-to-source voltages, VDS, as demonstrated in Equation 1:

$$Rdyn = \frac{VDS 2 - VDS 1}{ID 2 - ID 1} \qquad Equation 1$$

Wherein:
VDS1 is a first drain-to-source voltage measured for the NFET;
VDS2 is a second drain-to-source voltage measured for the NFET;
ID2 is a drain current of the NFET for VDS2; and
ID1 is a drain current of the NFET for VDS1.

The dynamic resistance 428, Rdyn and a current across the NFET 400, I_DUT (e.g., the current measured by the probe 264 of FIG. 2) is employable in Equation 2 to calculate a voltage of the NFET 400, V_DUT during the avalanche interval.

$$V\_DUT = Vbr + ( I\_DUT * Rdyn ) \qquad Equation 2$$

Wherein:
Rdyn is the dynamic resistance of the NFET;
Vbr is the breakdown voltage of the NFET; and
I_DUT is the current measured across the NFET.

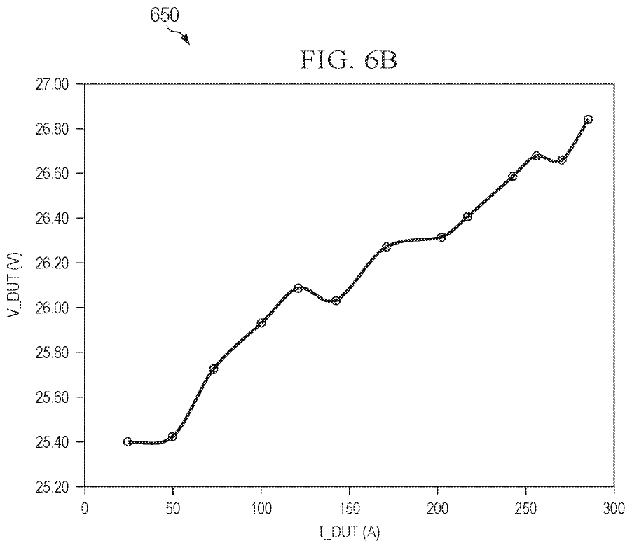

FIG. 6A illustrates a chart 600 of a sample of measured response characteristics of the NFET 400 during a DUT avalanche interval. The chart 600 includes parameters for the current across the NFET 400, I_DUT and parameters for the voltage across the NFET 400, V_DUT. The parameters for I_DUT include a maximum current in amperes, Max(A) and minimum current in amperes, Min(A), a rise time in nanoseconds, tr(ns), a fall time in nanoseconds, tf(ns) and a turn-on time for the NFET 400 in nanoseconds, ton(ns). The parameters for I_DUT also include a duration of the DUT avalanche interval in nanoseconds, I_DUT duration. The parameters for V_DUT of the NFET 400 include a minimum voltage, Min(V), a maximum voltage, Max(V) and an average voltage, Avg(V). FIG. 6B illustrates a graph 650 that plots the voltage, in volts (V) across the NFET 400 as a function of the current, in amperes (A) across the NFET 400.

Referring back to FIG. 3, at time t3, the test circuit 200 transitions to the TVS clamp state, wherein the second NFET 248 turns on. The test circuit 200 executes the TVS clamp state from times t3 to t4. As illustrated by the second graph 340, the inductor current of the inductor 212 decays at a rate that is less than the discharge rate during the DUT avalanche region. Also, as illustrated by the first graph 320, the drain-to-source voltage of the DUT 204 drops to a breakdown voltage of the TVS 246, Vbr_TVS. By the time the inductor 212 has fully discharged, at time t4, as indicated by the second graph 340, the drain-to-source voltage of the DUT 204 returns to Vs, such that the test circuit 200 transitions to the off state.

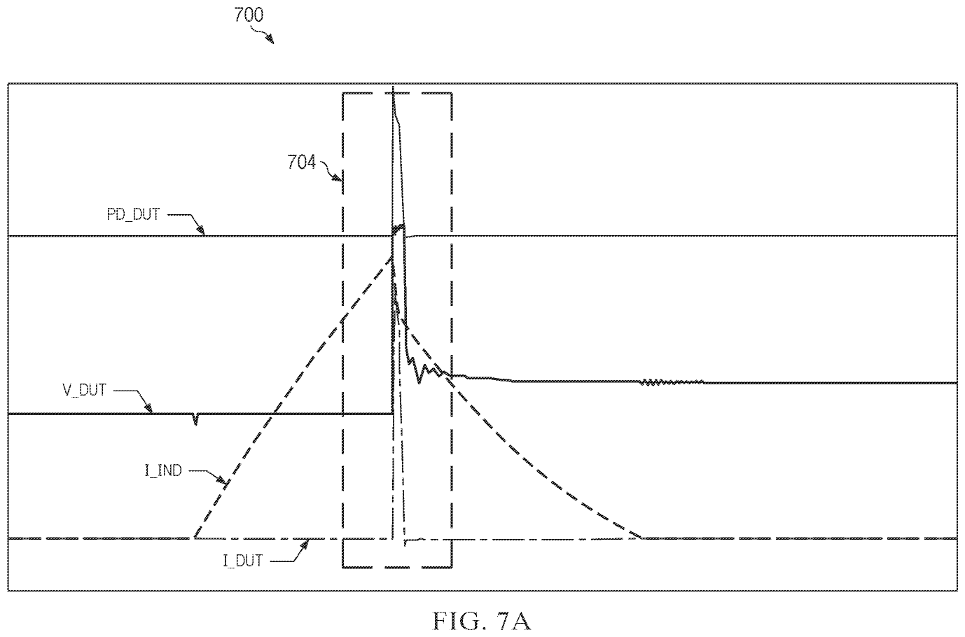

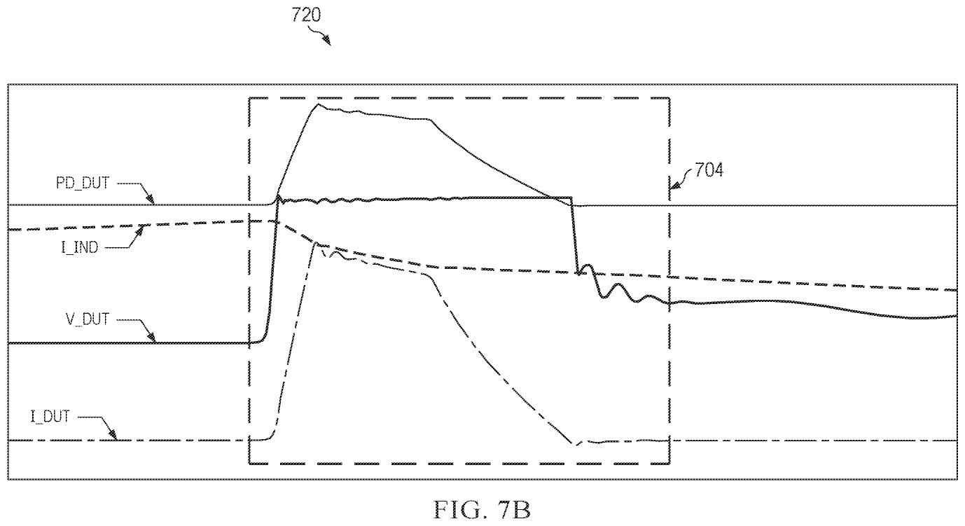

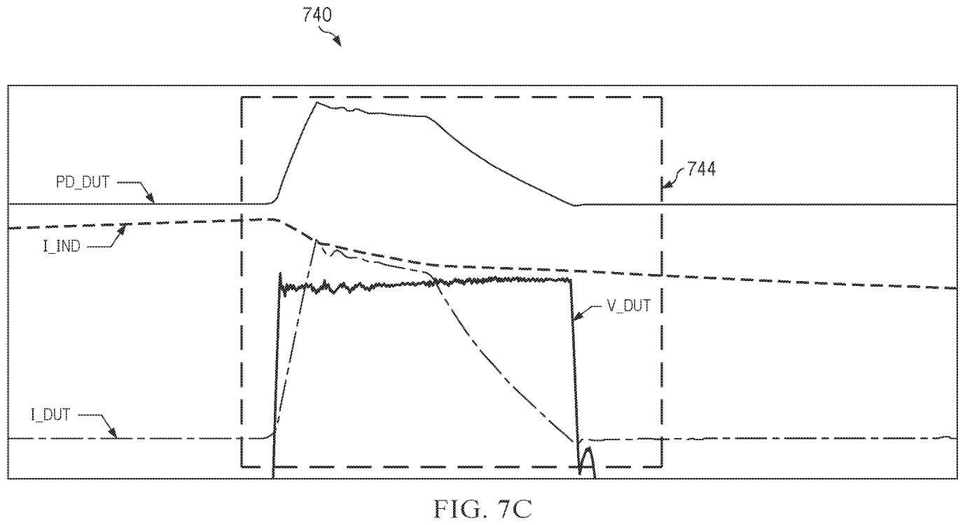

FIGS. 7A, 7B and 7C illustrate graphs that show measured results of a response of the DUT 204 of FIG. 2 to a first example of transient fault conditions during a DUT avalanche interval 704. FIGS. 7A, 7B and 7C plot a power dissipation by the DUT 204, PD_OUT, a voltage across the DUT 204, V_DUT, a current across the DUT 204, I_DUT and a current discharged by the inductor 212, I_IND. More particularly, FIG. 7A depicts a first graph 700 that includes a DUT avalanche interval 704. FIG. 7B illustrates a second graph 720 that represents a portion of the first graph 700 with a zoomed in region that includes the DUT avalanche interval 704. FIG. 7C illustrates a third graph 740 that includes a DUT avalanche interval 744 wherein a DC offset of 20 V has been applied to the voltage across the DUT 204, V_DUT. In the example illustrated, it is presumed that transient fault conditions of a single pulse of 100 A of avalanche current is applied to the DUT 204 during the DUT avalanche interval 704 and the DUT avalanche interval 744. In the example illustrated, there is no deviation in operating parameters of the DUT 204 before or after the transient fault conditions of a 100 A avalanche current is applied to the DUT 204.

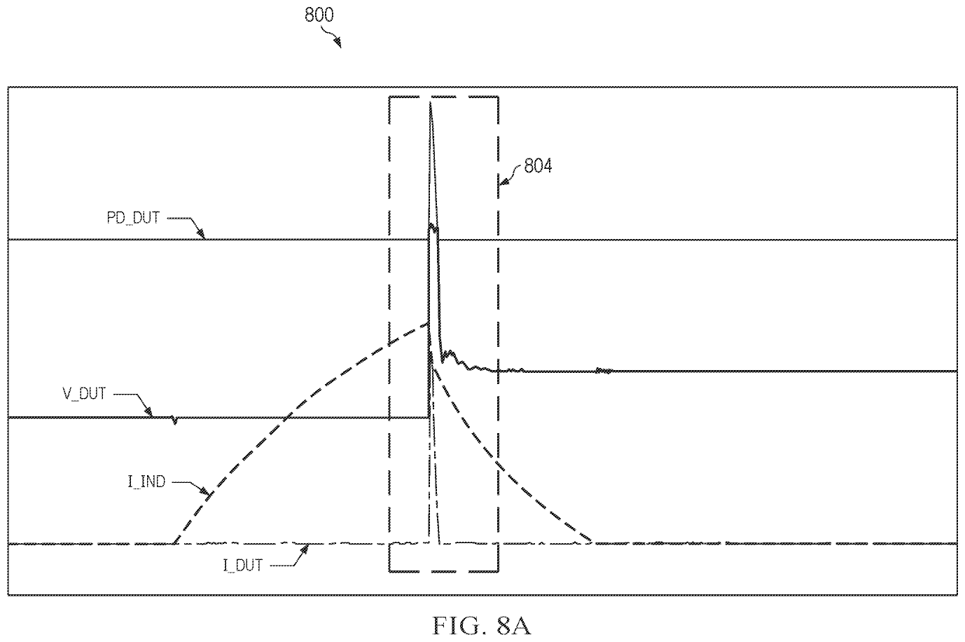

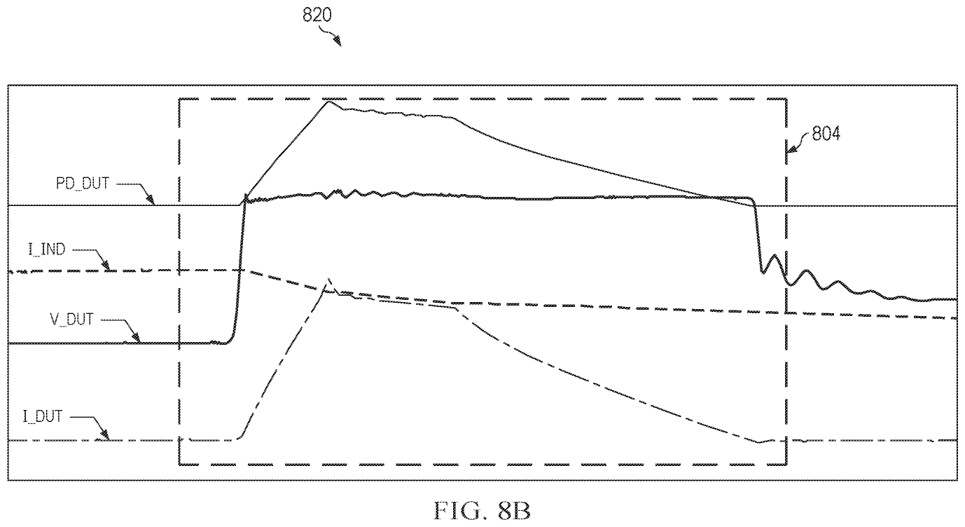

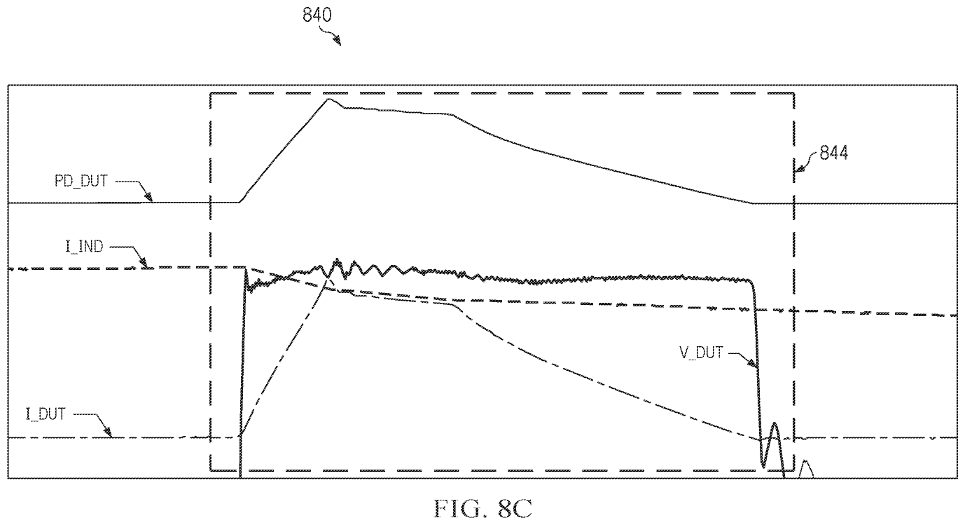

FIGS. 8A, 8B and 8C illustrate graphs that show measured results of a response of the DUT 204 of FIG. 2 to a second example of transient fault conditions during a DUT avalanche interval. FIGS. 8A, 8B and 8C plot a power dissipation by the DUT 204, PD_OUT, a voltage across the DUT 204, V_DUT, a current across the DUT 204, I_DUT and a current discharged by the inductor 212, I_IND. More particularly, FIG. 8A depicts a first graph 800 that includes a DUT avalanche interval 804. FIG. 8B illustrates a second graph 820 that represents a portion of the first graph 800 with a zoomed in region that includes the DUT avalanche interval 804. FIG. 8C illustrates a third graph 840 that includes a DUT avalanche interval 844 wherein a DC offset of 20 V has been applied to the voltage across the DUT 204, V_DUT. In the example illustrated, it is presumed that transient fault conditions of a single pulse of 200 A of avalanche current is applied to the DUT 204 during the DUT avalanche interval 804 and the DUT avalanche interval 844. In the example illustrated, there is no deviation in operating parameters of the DUT 204 before or after the transient fault conditions of a 200 A avalanche current is applied to the DUT 204.

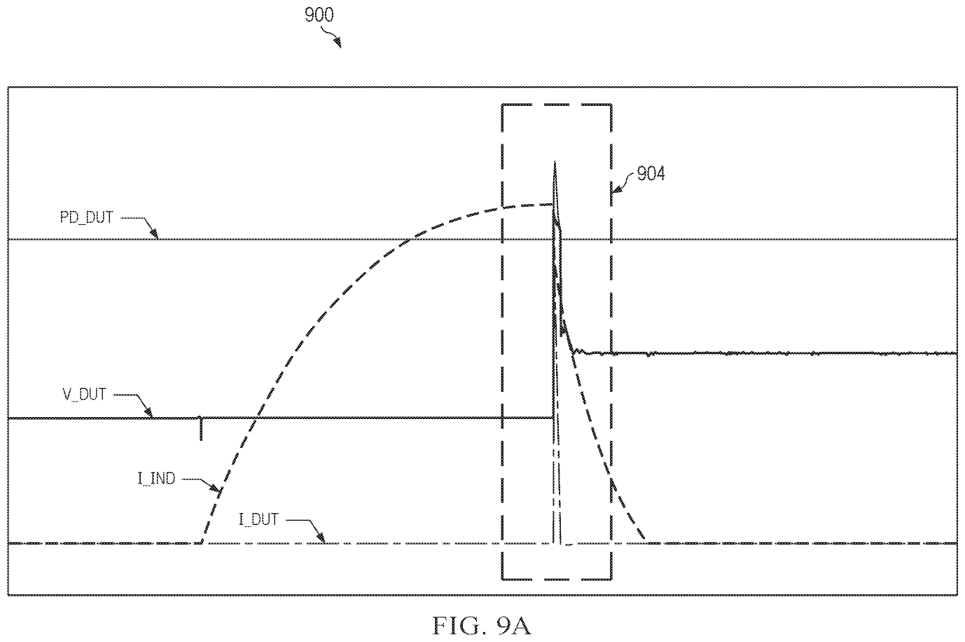

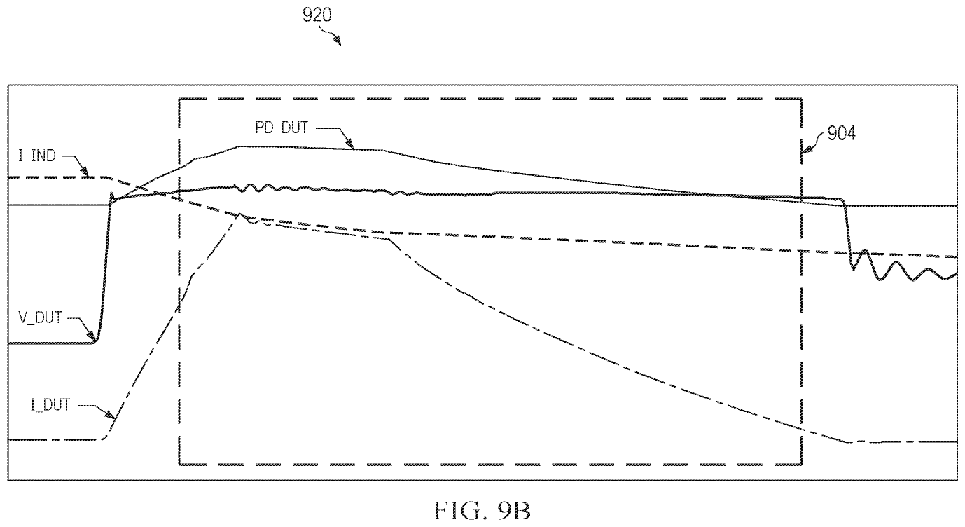

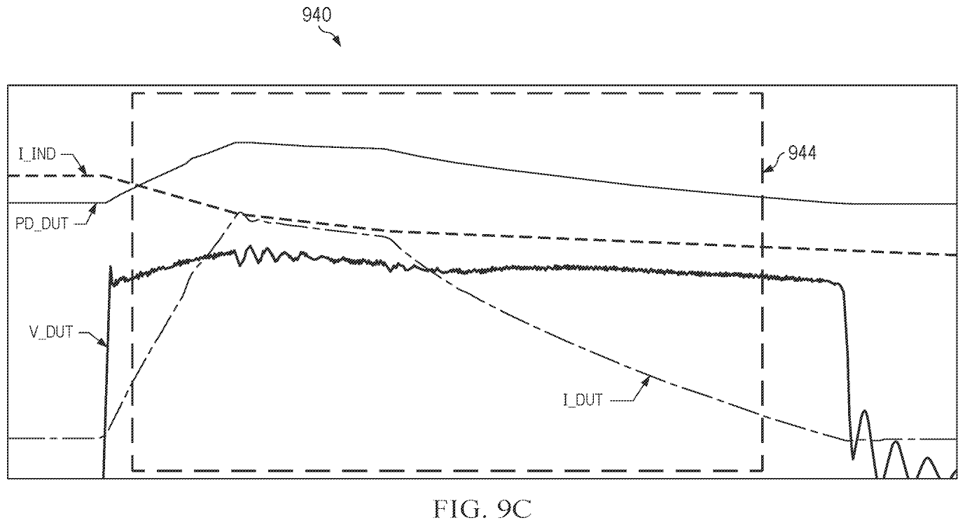

FIGS. 9A, 9B and 9C illustrate graphs that show measured results of a response of the DUT 204 of FIG. 2 to a third example of transient fault conditions during a DUT avalanche interval. FIGS. 9A, 9B and 9C plot a power dissipation by the DUT 204, PD_OUT, a voltage across the DUT 204, V_DUT, a current across the DUT 204, I_DUT and a current discharged by the inductor 212, I_IND. More particularly, FIG. 9A depicts a first graph 900 that includes a DUT avalanche interval 904. FIG. 9B illustrates a second graph 920 that represents a portion of the first graph 900 with a zoomed in region that includes the DUT avalanche interval 904. FIG. 9C illustrates a third graph 940 that includes a DUT avalanche interval 944 wherein a DC offset of 20 V has been applied to the voltage across the DUT 204, V_DUT. In the example illustrated, it is presumed that transient fault conditions of a single pulse of 288 A of avalanche current is applied to the DUT 204 during the DUT avalanche interval 904 and the DUT avalanche interval 944. In the example illustrated, there is no deviation in operating parameters of the DUT 204 before or after the transient fault conditions of a 288 A avalanche current is applied to the DUT 204.

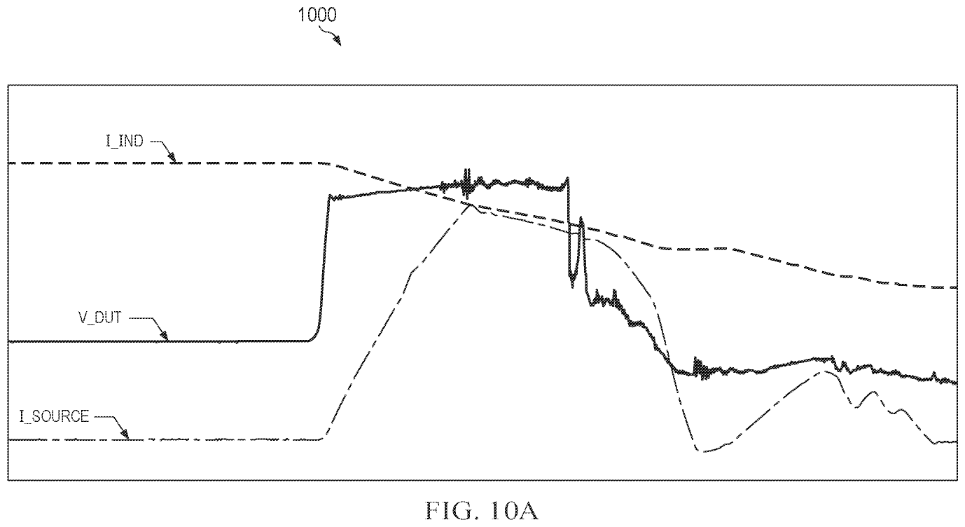

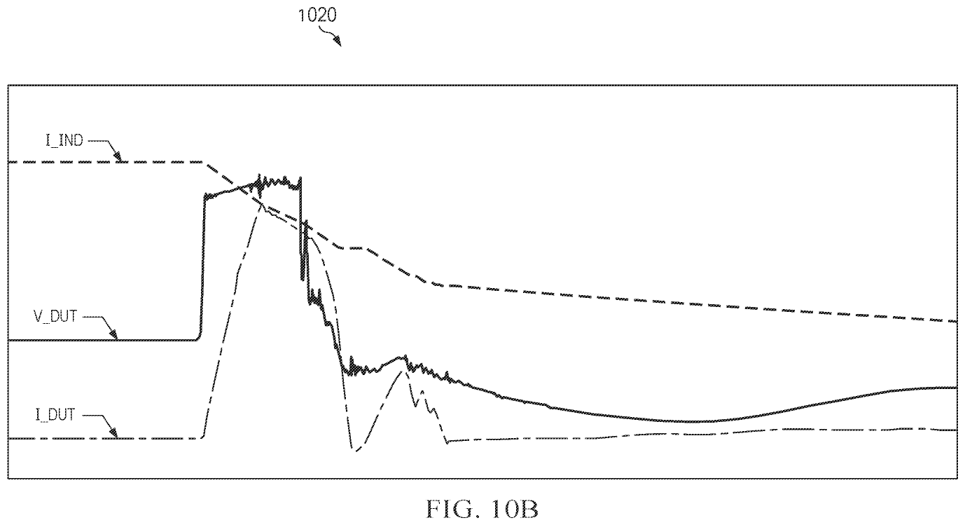

FIGS. 10A and 10B illustrate graphs that show measured results of a response of the DUT 204 of FIG. 2 to a fourth example of transient fault conditions during a DUT. FIGS. 10A and 10B plot a power dissipation by the DUT 204, PD_OUT, a voltage across the DUT 204, V_DUT, a current across the DUT 204, I_DUT and a current discharged by the inductor 212, I_IND. More particularly, FIG. 10A depicts a first graph 1000 for a DUT avalanche interval. FIG. 10B illustrates a second graph 1020 that includes a DUT avalanche interval wherein a DC offset of 20 V has been applied to the voltage across the DUT 204, V_DUT. In the example illustrated, it is presumed that transient fault conditions of a single pulse of 300 A of avalanche current is applied to the DUT 204 during the DUT avalanche interval. In the example illustrated, the DUT 204 shorts, indicating that there DUT 204 has failed, such that the single pulse of 300 A of avalanche current exceeds ratings of the DUT 204.

Referring back to FIG. 2, in the example illustrated by FIGS. 9A, 9B and 9C, the DUT 65—Thus, in this situation, the DUT 204 is employable (e.g., as an eFuse) for systems that may experience transient fault conditions of a current spike of 288 A or less.

Further, in some situations, multiple DUT avalanche intervals are applied on the DUT 204 to test reliability of the DUT 204. In such a situation, the controller 260 can reassert and de-assert the control signals to the power supply 224, the first NFET 240 and the second NFET 248 to transition the test circuit 200 to the inductor charging state, the DUT avalanche state and the TVS clamp state. Accordingly, the impact of multiple transient fault conditions (multiple instances of the DUT avalanche interval) can be measured and recorded.

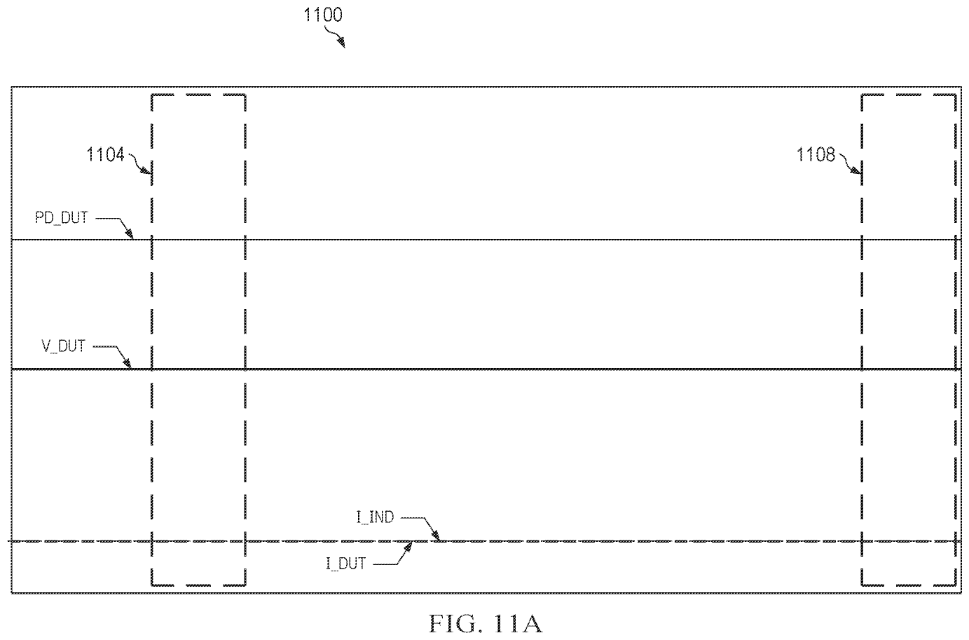

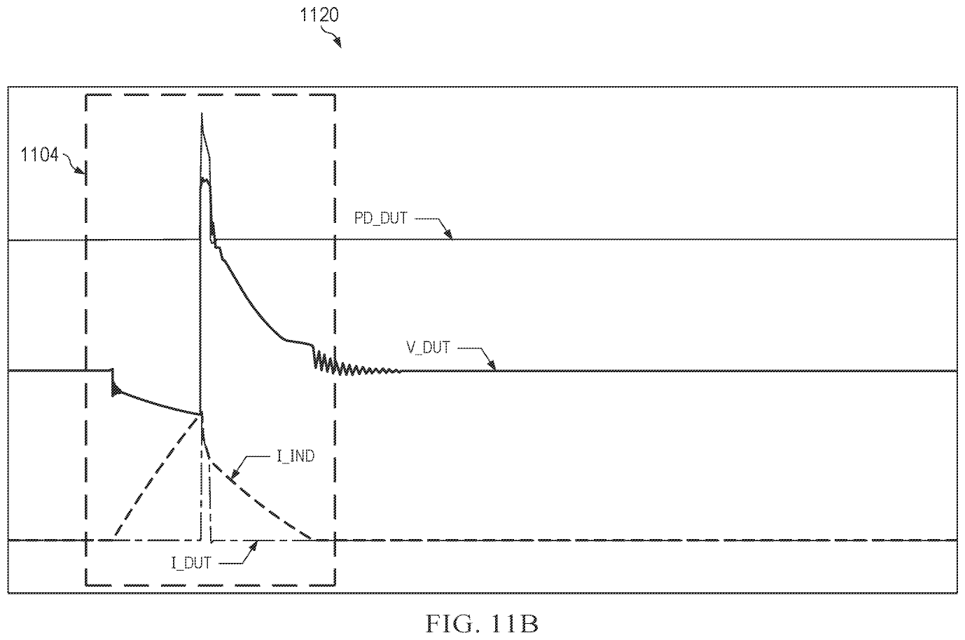

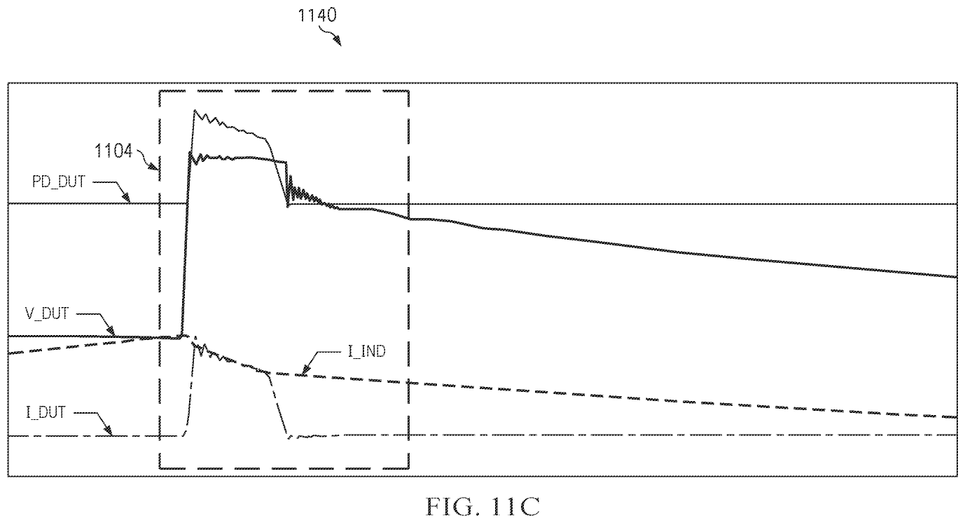

FIGS. 11A, 11B and 11C illustrate graphs that show measured results of a response of the DUT 204 of FIG. 2 to a first example of repetitive transient fault conditions during multiple DUT avalanche intervals. More particularly, FIGS. 11A, 11B and 11C plot a power dissipation by the DUT 204, PD_OUT, a voltage across the DUT 204, V_DUT, a current across the DUT 204, I_DUT and a current discharged by the inductor 212, I_IND. FIG. 11A depicts a first graph 1100 that includes a first DUT avalanche interval 1104 and a second DUT avalanche interval 1108. FIG. 11B illustrates a second graph 1120 that represents a portion of the first graph 1100 with a zoomed in region that includes the first DUT avalanche interval 1104. FIG. 11C illustrates a third graph 1140 that includes a further zoomed in region of the first DUT avalanche interval 1104. In the example illustrated, it is presumed that transient fault conditions of repetitive pulses of an avalanche current of 50 A for 1 μs at a frequency of 1 Hertz (Hz) applied to the DUT 204 during the first DUT avalanche interval 1104. In the example illustrated, there is no deviation in operating parameters of the DUT 204 after the transient fault conditions of 2000 repetitive pulses of 50 A for 1 μs at a frequency of 1 Hz.

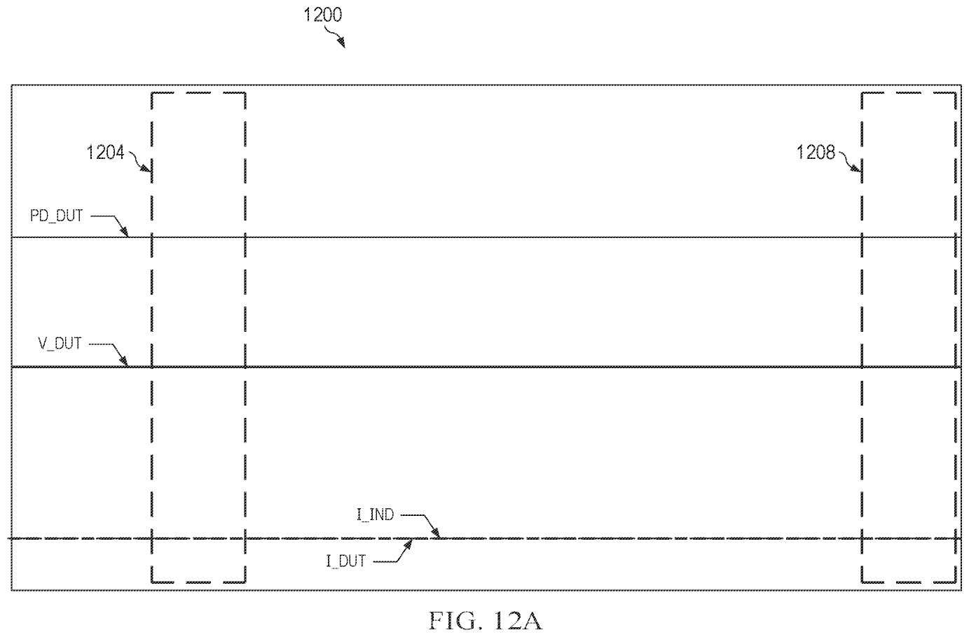

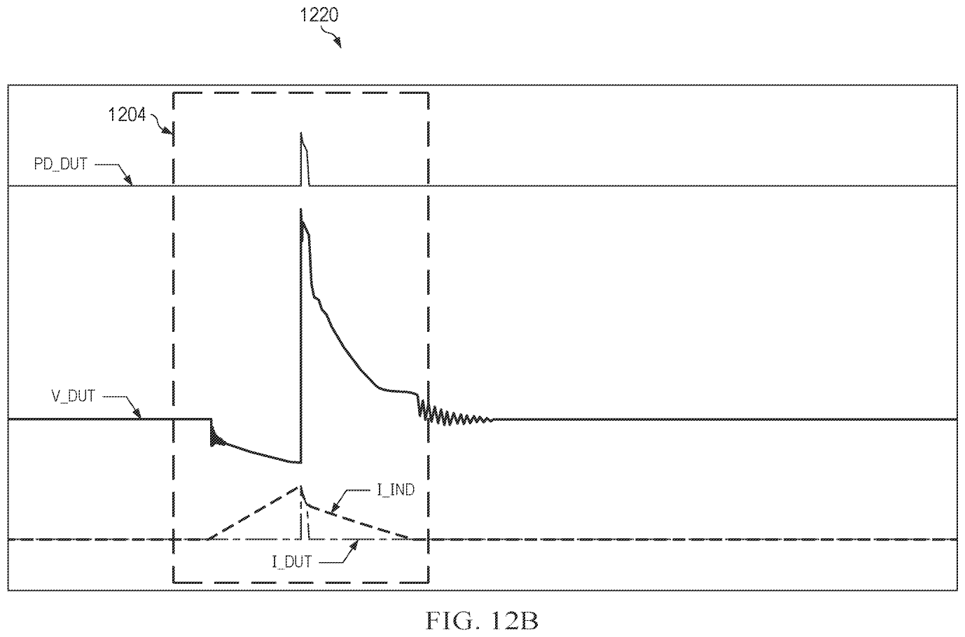

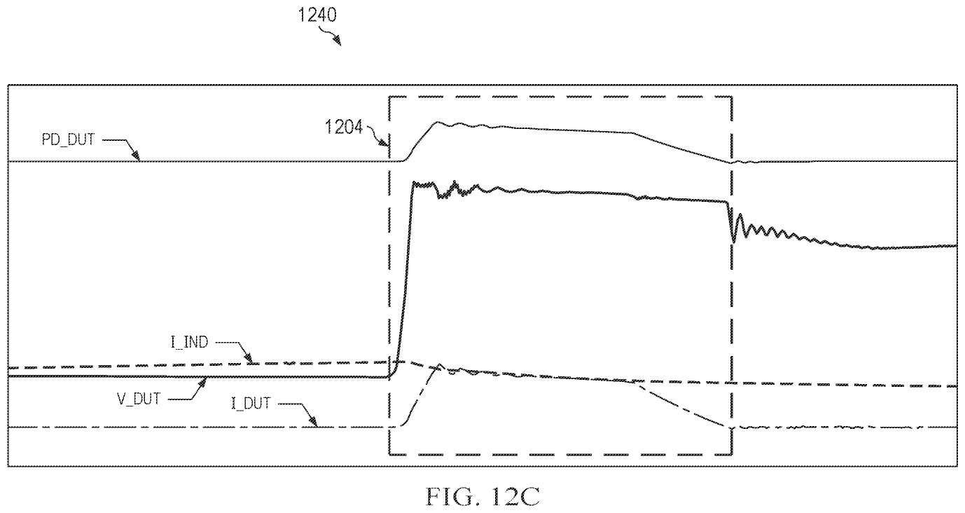

FIGS. 12A, 12B and 12C illustrate graphs that show measured results of a response of the DUT 204 of FIG. 2 to a second example of repetitive transient fault conditions during multiple DUT avalanche intervals. More particularly, FIGS. 12A, 12B and 12C plot a power dissipation by the DUT 204, PD_OUT, a voltage across the DUT 204, V_DUT, a current across the DUT 204, I_DUT and a current discharged by the inductor 212, I_IND. FIG. 12A depicts a first graph 1200. The first graph 1200 includes a first DUT avalanche interval 1204 and a second DUT avalanche interval 1208. FIG. 12B illustrates a second graph 1220 that represents a portion of the first graph 1200 with a zoomed in region that includes the first DUT avalanche interval 1204. FIG. 12C illustrates a third graph 1240 that includes a further zoomed in region of the first DUT avalanche interval 1204. In the example illustrated, it is presumed that transient fault conditions of repetitive pulses of an avalanche current of 75 A for 1 μs at a frequency of 1 Hertz (Hz) applied to the DUT 204 during the first DUT avalanche interval 1204. In the example illustrated, there is no deviation in operating parameters of the DUT 204 after the transient fault conditions of 2000 repetitive pulses of 75 A for 1 μs at a frequency of 1 Hz.

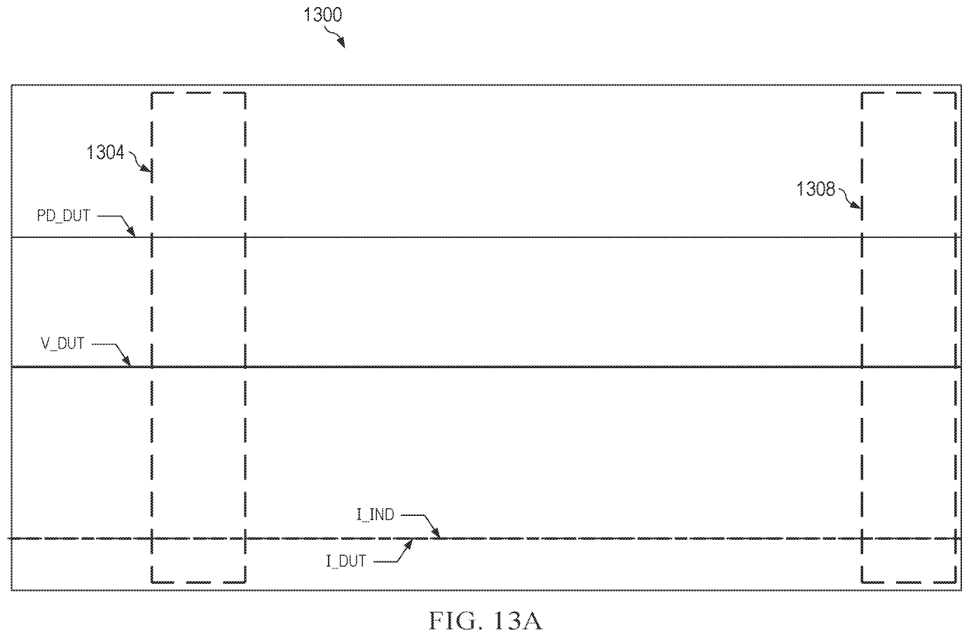

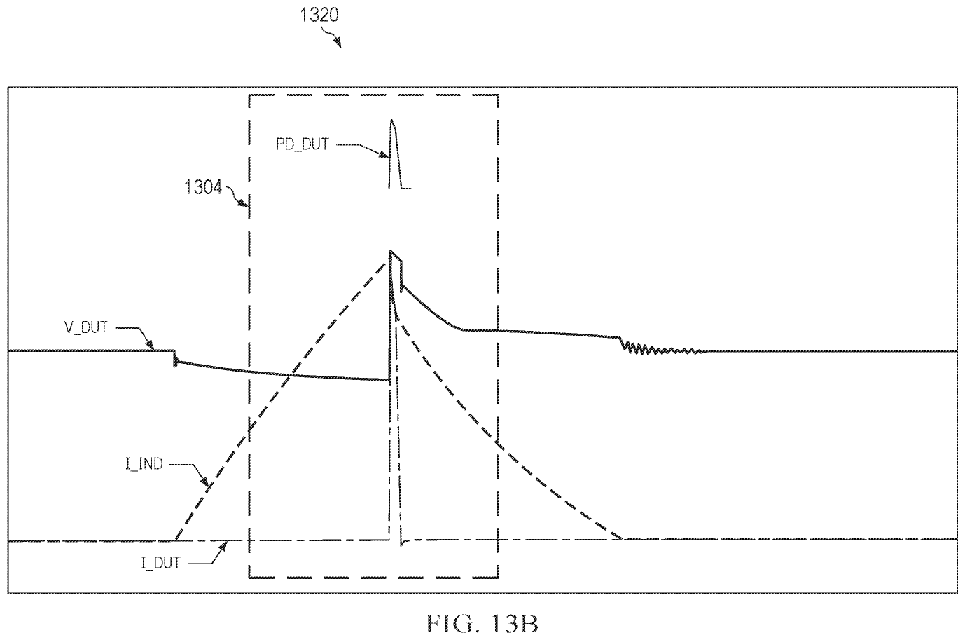

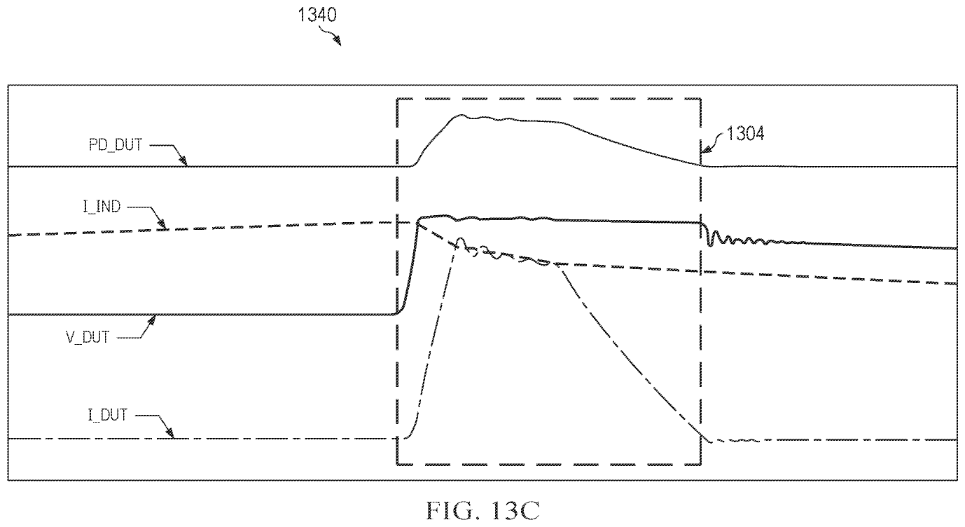

FIGS. 13A, 13B and 13C illustrate graphs that show measured results of a response of the DUT 204 of FIG. 2 to a third example of repetitive transient fault conditions during multiple DUT avalanche intervals. More particularly, FIGS. 13A, 13B and 13C plot a power dissipation by the DUT 204, PD_OUT, a voltage across the DUT 204, V_DUT, a current across the DUT 204, I_DUT and a current discharged by the inductor 212, I_IND. FIG. 13A depicts a first graph 1300 that includes a first DUT avalanche interval 1304 and a second DUT avalanche interval 1308. FIG. 13B illustrates a second graph 1320 that represents a portion of the first graph 1300 with a zoomed in region that includes the first DUT avalanche interval 1304. FIG. 13C illustrates a third graph 1340 that includes a further zoomed in region of the first DUT avalanche interval 1304. In the example illustrated, it is presumed that transient fault conditions of repetitive pulses of an avalanche current of 100 A for 1 μs at a frequency of 1 Hertz (Hz) applied to the DUT 204 during the first DUT avalanche interval 1304 cause a failure of the DUT 204. In the example illustrated, the DUT 204 shorts in response to 40 instances the repetitive pulses of an avalanche current of 100 A for 1 μs, indicating a failure of the DUT 204.

Referring back to FIG. 2, as demonstrated in the example of FIGS. 12A, 12B and 12C, the DUT 204 has a current rating of repetitive pulses 75 A for a duration of about 1 μs or less at a frequency of 1 Hz or less. Thus, in this situation, the DUT 204 is employable (e.g., as an eFuse) for systems that may experience transient fault conditions of repetitive pulses 75 A for a duration of about 1 μs or less at a frequency of 1 Hz or less.

As demonstrated, the architecture of the test circuit 200, particularly the first NFET 240 and the second NFET 248, enables precise controlling of the amplitude of the fault conditions and the duration of the DUT avalanche interval. Accordingly, precise transient voltage and/or current ratings for the DUT 204 can be determined. In this manner, the DUT 204 (e.g., an eFuse) can be confidently deployed in other circuits that rely on particular operational characteristics present in the fault conditions applied during the DUT avalanche interval. Thus, in examples where the DUT 204 is an eFuse, the transient voltage and current rating of the eFuse characterize an ability of the eFuse to protect a downstream load during an overload and/or a short circuit condition.

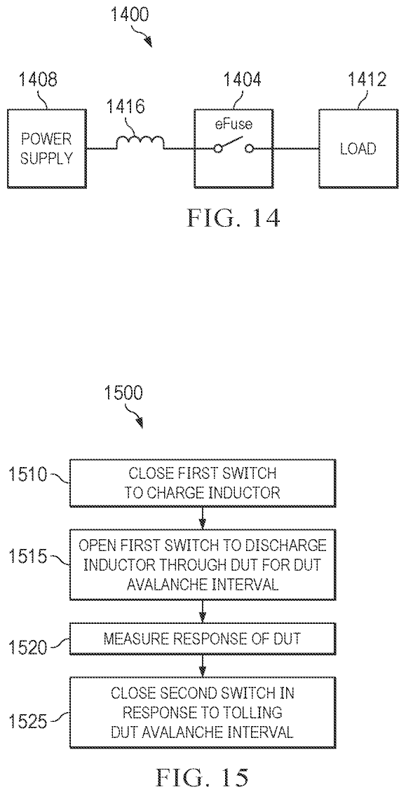

FIG. 14 illustrates a block diagram of a circuit 1400 that illustrates an eFuse 1404 coupled between a power supply 1408 and a load 1412. In this manner, the load 1412 is downstream from the eFuse 1404. The eFuse 1404 is employable to implement the DUT 104 of FIG. 1 and/or the DUT 204 of FIG. 2. An inductor 1416 is coupled between the power supply 1408 and the eFuse 1404. The load 1412 is implemented as a resistance and/or reactive load. In the example illustrated, it is presumed that the eFuse 1404 could be exposed to transient fault conditions similar to those explained with respect to FIGS. 1 and 2.

In operation, the power supply 1408 provides a DC voltage to the load 1412 through the eFuse 1404. Thus, the eFuse 1404 is normally closed. Additionally, the eFuse 1404 serves as a resettable overcurrent protection device for the circuit 1400. When current levels exceed predefined limits, the eFuse acts quickly to break the current path between the power supply 1408 and the load 1412, thereby preventing damage to the load 1412 during overload and/or short circuit conditions. Moreover, the eFuse 1404 is resettable after being tripped.

FIG. 15 illustrates a flowchart of an example method 1500 for determining characteristics of a DUT. The DUT is implemented with an eFuse in some examples. In some examples, the method 1500 is implemented with the test circuit 100 of FIG. 1. At block 1510, a first switch (e.g., the first switch 140 of FIG. 1) of the test circuit is closed to pre-charge an inductor (e.g., the inductor 112 of FIG. 1) of the test circuit. The first switch is implemented with a FET in some examples. At block 1515, the first switch is opened to discharge the inductor through the DUT to apply a transient fault condition for a DUT avalanche interval. At block 1520, a response of the DUT to the transient fault condition is measured.

At block 1525, a second switch (e.g., the second switch 148 of FIG. 1) is closed responsive to tolling the DUT avalanche interval to divert inductor current from the DUT to a TVS. The TVS clamps the voltage across the eFuse in response to the closing of the second switch. In some examples, the second switch is also implemented with a FET. The circuit is configured such that a controller (e.g., the controller 160 of FIG. 1) outputs control signals to the first and second switches to control a duration of the DUT avalanche interval.

In this description, unless otherwise stated, “about” preceding a parameter means being within +/−10 percent of that parameter. Further, in this description, the term “couple”, “coupled” or “couples” means either an indirect or direct connection. Modifications are possible in the described embodiments, and other embodiments are possible, within the scope of the claims.

What is claimed is:

1. A circuit for determining characteristics of a DUT (device under test), comprising:
an inductor coupled to a first switch;
the first switch coupled to a second switch;
a test module coupled to the first switch and the second switch, the test module comprising a DUT; and
a TVS (transient voltage suppressor) coupled to the second switch.

2. The circuit of claim 1, wherein the DUT is an eFuse.

3. The circuit of claim 2, wherein the test module further comprises a discharge resistor coupled in parallel with the eFuse.

4. The circuit of claim 3, wherein the circuit further comprises a diode coupled to the first switch, the second switch, the eFuse and the discharge resistor.

5. The circuit of claim 4, further comprising a power supply configured to apply voltage to the inductor.

6. The circuit of claim 5, wherein the TVS is configured to clamp the voltage to a predetermined level responsive to closing the second switch.

7. The circuit of claim 6, further comprising a controller configured to adjust timing control signals output to the first switch and the second switch to vary a DUT avalanche interval, the DUT avalanche interval comprising an interval of time between an opening of the first switch and the closing of the second switch.

8. The circuit of claim 1, wherein the first switch and the second switch are FETs (field effect transistors).

9. A circuit for determining characteristics of a DUT (device under test) comprising:
an inductor configured to store energy;
a first switch coupled to the inductor and operable to provide a charging path for the inductor;
a second switch coupled to the first switch, wherein the first switch and the second switch operate in concert to control a discharge of the inductor through a first discharge path, and the second switch is operable to provide a second discharge path for the inductor responsive to tolling a DUT avalanche interval;
a TVS (transient voltage suppressor) on the second discharge path, the TVS being coupled to the second switch, wherein the energy from the inductor is diverted to the TVS responsive to the tolling of the DUT avalanche interval; and
a test module on the first discharge path that is coupled to the first switch and the second switch, wherein the test module connects the DUT to a current output by the inductor during the DUT avalanche interval for testing current ratings of the DUT.

10. The circuit of claim 9, wherein the DUT is an eFuse.

11. The circuit of claim 10, wherein the inductor, the first switch, the second switch and the TVS are configured to apply a transient fault condition on the DUT during the DUT avalanche interval, the DUT avalanche interval comprising an interval of time between an opening of the first switch and a closing of the second switch.

12. The circuit of claim 11, wherein the DUT avalanche interval is adjustable based on timing control signals.

13. The circuit of claim 12, further comprising a controller configured to adjust the timing control signals to vary the DUT avalanche interval.

14. The circuit of claim 10, wherein the TVS is configured to clamp the voltage to a predetermined level responsive to the tolling of the DUT avalanche interval.

15. The circuit of claim 10, wherein the current ratings for the eFuse characterize an ability of the eFuse to protect a downstream load during an overload and/or short circuit condition.

16. The circuit of claim 9, wherein the first switch and the second switch are FETs (field effect transistors).

17. A method for determining characteristics a DUT (device under test) comprising:
closing a first switch of a circuit to pre-charge an inductor of the circuit;
opening the first switch to discharge the inductor through the DUT to apply a transient fault condition for a DUT avalanche interval;
measuring a response of the DUT to the transient fault condition; and
closing a second switch responsive to tolling the DUT avalanche interval to divert inductor current to a TVS (transient voltage suppressor).

18. The method of claim 17, wherein the DUT is an eFuse.

19. The method of claim 18, wherein the TVS clamps a voltage across the eFuse in response to the closing of the second switch.

20. The method of claim 17, wherein the first switch and the second switch are FETs (field effect transistors).

21. The method of claim 17, wherein a controller outputs control signals to the first switch and the second switch to control a duration of the DUT avalanche interval.
